(19) United States
(12) Patent Application Publication
(10) Pub. No.: US 2013/0109124 A1
(43) Pub. Date: May 2, 2013

(54) METHODS OF MAKING A TRANSPARENT LAYER AND A PHOTOVOLTAIC DEVICE

(71) Applicants: Hongying Peng, Clifton Park, NY (US); Juan Carlos Rojo, Niskayuna, NY (US); Hongbo Cao, Cohoes, NY (US); George Theodore Dalakos, Niskayuna, NY (US); Holly Ann Blaydes, Burnt Hills, NY (US); David William Vernooy, Niskayuna, NY (US); Mark Jeffrey Pavol, Arvada, CO (US); Jae Hyuk Her, Niskayuna, NY (US); Hong Piao, Rexford, NY (US); Robert Dwayne Gossman, Aurora, CO (US); Scott Daniel Feldman-Peabody, Golden, CO (US); Yangang Andrew Xi, Prairie, MN (US)

(72) Inventors: Hongying Peng, Clifton Park, NY (US); Juan Carlos Rojo, Niskayuna, NY (US); Hongbo Cao, Cohoes, NY (US); George Theodore Dalakos, Niskayuna, NY (US); Holly Ann Blaydes, Burnt Hills, NY (US); David William Vernooy, Niskayuna, NY (US); Mark Jeffrey Pavol, Arvada, CO (US); Jae Hyuk Her, Niskayuna, NY (US); Hong Piao, Rexford, NY (US); Robert Dwayne Gossman, Aurora, CO (US); Scott Daniel Feldman-Peabody, Golden, CO (US); Yangang Andrew Xi, Prairie, MN (US)

(73) Assignee: GENERAL ELECTRIC COMPANY, SCHENECTADY, NY (US)

(21) Appl. No.: 13/284,037

(22) Filed: Oct. 28, 2011

(51) Int. Cl. H01L 31/18; H01L 31/0296; H01L 31/0224

(52) U.S. Cl. 438/58; 438/98; 438/94; 257/E31.015; 257/E31.126

(57) ABSTRACT

In one aspect of the present invention, a method is included. The method includes thermally processing an assembly to form at least one transparent layer. The assembly includes a first panel including a first layer disposed on a first support and a second panel including a second layer disposed on a second support, wherein the second panel faces the first panel, and wherein the first layer and the second layer include substantially amorphous cadmium tin oxide. Method of making a photovoltaic device is also included.

### BACKGROUND

The invention generally relates to methods for forming transparent layers. More particularly, the invention relates to methods for forming transparent layers including cadmium tin oxide for photovoltaic devices

Thin film solar cells or photovoltaic devices typically include a plurality of semiconductor layers disposed on a transparent substrate, wherein one layer serves as a window layer and a second layer serves as an absorber layer. The window layer allows the penetration of solar radiation to the absorber layer, where the optical energy is converted to usable electrical energy. Cadmium telluride/cadmium sulfide (CdTe/CdS) heterojunction-based photovoltaic cells are one such example of thin film solar cells

Typically, a thin layer of transparent conductive oxide (TCO) is deposited between the substrate and the window layer (for example, CdS) to function as a front contact current collector. However conventional TCOs, such as tin oxide, indium tin oxide, and zinc oxide, have high electrical resistivities at thickness necessary for good optical transmission. The use of cadmium tin oxide (CTO) as TCO may provide better electrical and optical properties than conventional TCOs.

The typical method used to manufacture a high quality CTO layer includes depositing a layer of amorphous cadmium tin oxide on a substrate, followed by slow thermal annealing of the CTO layer, which is annealed in the presence of a CdS film in close proximity to the surface of the CTO film, to achieve desired transparency and resistivity. The use of expensive CdS for each annealing step may be economically disadvantageous for large-scale manufacturing as the CdS film is not reusable and the cost of the CdS and the glass support makes the process expensive on a large scale. Further, CdS-based annealing of CTO is difficult to implement in a large-scale continuous manufacturing environment, as the process requires assembly and disassembly of plates before and after the annealing steps.

Thus, there is a need for improved methods of annealing of CTO layer during manufacturing of photovoltaic devices, resulting in reduced costs and improved manufacturing capability. Further, there is a need for cost-effective methods of annealing of CTO to obtain transparent crystalline CTO layers having the desired optical and electrical properties.

### BRIEF DESCRIPTION OF THE INVENTION

Embodiments of the present invention are included to meet these and other needs. One embodiment is a method. The method includes thermally processing an assembly to form at least one transparent layer. The assembly includes a first panel including a first layer disposed on a first support and a second panel including a second layer disposed on a second support, wherein the second panel faces the first panel, and wherein the first layer and the second layer include substantially amorphous cadmium tin oxide.

Another embodiment is a method. The method includes thermally processing a stack including a plurality of assemblies to form a plurality of transparent layers. Each assembly includes a first panel including a first layer disposed on a first support and a second panel including a second layer disposed on a second support, wherein the second panel faces the first panel, and wherein the first layer and the second layer include substantially amorphous cadmium tin oxide.

Another embodiment is a method of making a photovoltaic device. The method includes thermally processing an assembly to form at least one transparent layer. The assembly includes a first panel including a first layer disposed on a first support and a second panel including a second layer disposed on a second support, wherein the second panel faces the first panel, and wherein the first layer and the second layer include substantially amorphous cadmium tin oxide. The method further includes separating the first panel from the second panel, disposing a first semiconductor layer on the transparent layer, disposing a second semiconductor layer on the first semiconductor layer, and disposing a back contact layer on the second semiconductor layer to form the photovoltaic device.

Another embodiment is a method. The method includes thermally processing an assembly to form a first transparent layer and a second transparent layer. The assembly includes a first panel including a first layer disposed on a first support and a first getter layer disposed on the first layer or between the first layer and the first support. The assembly further includes a second panel including a second layer disposed on a second support and a second getter layer disposed on the second layer or between the second layer and the second support. The second panel faces the first panel, and the first layer and the second layer include substantially amorphous cadmium tin oxide.

### DRAWINGS

These and other features, aspects, and advantages of the present invention will become better understood when the following detailed description is read with reference to the accompanying drawings, wherein:

FIG. 1 is a schematic of an assembly before thermal processing, according to an exemplary embodiment of the invention.

FIG. 2 is a schematic of a disassembled assembly before thermal processing, according to an exemplary embodiment of the invention.

FIG. 3 is a schematic of an assembly after thermal processing, according to an exemplary embodiment of the invention.

FIG. 4 is a schematic of a disassembled assembly after thermal processing, according to an exemplary embodiment of the invention.

FIG. 5 is a schematic of an assembly before thermal processing, according to an exemplary embodiment of the invention.

FIG. 6 is a schematic of an assembly after thermal processing, according to an exemplary embodiment of the invention.

FIG. 7 is a schematic of an assembly before thermal processing, according to an exemplary embodiment of the invention.

FIG. 8 is a schematic of an assembly after thermal processing, according to an exemplary embodiment of the invention.

FIG. 9 is a schematic of an assembly before thermal processing, according to an exemplary embodiment of the invention.

FIG. 10 is a schematic of an assembly after thermal processing, according to an exemplary embodiment of the invention.

FIG. 11 is a schematic of an assembly before thermal processing, according to an exemplary embodiment of the invention.

FIG. 12 is a schematic of an assembly after thermal processing, according to an exemplary embodiment of the invention.

FIG. 13 is a schematic of an assembly before thermal processing, according to an exemplary embodiment of the invention.

FIG. 14 is a schematic of an assembly after thermal processing, according to an exemplary embodiment of the invention.

FIG. 15 is a schematic of a photovoltaic device, according to an exemplary embodiment of the invention.

FIG. 16 is a schematic of a photovoltaic device, according to an exemplary embodiment of the invention.

FIG. 17 is a schematic of a photovoltaic device, according to an exemplary embodiment of the invention.

FIG. 18 is a schematic of a stack including a plurality of assemblies, according to an exemplary embodiment of the invention.

FIG. 19 shows a graph of sheet resistance versus gap width, according to an exemplary embodiment of the invention.

FIG. 20A shows the XPS depth profile of CTO film annealed using close proximity annealing.

FIG. 20B shows the XPS depth profile of CTO film annealed using standard thermal annealing.

FIG. 20C shows the XPS depth profile of CTO film annealed using face-to-face annealing.

FIG. 21A shows the GIXRD patterns at glancing incident angle of 0.3 degree for CTO films annealed using different annealing methods.

FIG. 21B shows the GIXRD patterns at glancing incident angle of 0.8 degree for CTO films annealed using different annealing methods.

FIG. 22 shows a graph of sheet resistance versus getter layer material, according to an exemplary embodiment of the invention.

### DETAILED DESCRIPTION

As discussed in detail below, some of the embodiments of the invention include a method for forming a transparent layer by face to face annealing. Some other embodiments of the invention include a method for forming a transparent layer of crystalline cadmium tine oxide (CTO) by face to face annealing. The methods may enable a cost-effective manufacturable process for forming crystalline cadmium tin oxide by eliminating the use of an expensive CdS/glass sacrificial part, typically used in CdS proximity annealing, in some embodiments. Further, in some embodiments, the methods of the present invention may advantageously limit evaporation or diffusion of cadmium from the CTO layers during the annealing process by creating an overpressure of cadmium vapor through the use of a second CTO layer deposited on a support. In embodiments including a getter layer, the methods of the present may further advantageously provide for removal of oxygen from the CTO layer while limiting diffusion of cadmium from the CTO layer during the annealing process, which may lead to increase in carrier concentration of the annealed CTO layer and improved electrical and optical properties. Furthermore, by face-to-face annealing of two CTO layers, the annealing process of the present invention may also result in reduced processing time leading to higher throughputs, which may lead to lower manufacturing costs.

The crystalline cadmium tin oxide films manufactured according to some embodiments of the invention have electrical and optical properties comparable to cadmium tin oxide films annealed using CdS layer. In some embodiments, the amorphous cadmium tin oxide film is annealed advantageously in the absence of a sacrificial layer of cadmium sulfide to obtain electrical resistivity less than about 2×10⁻⁴ Ohm-cm and optical absorption less than about 5%. Methods for making crystalline CTO films having such an advantageous combination of electrical and optical properties are included, according to some embodiments of the present invention.

Approximating language, as used herein throughout the specification and claims, may be applied to modify any quantitative representation that could permissibly vary without resulting in a change in the basic function to which it is related. Accordingly, a value modified by a term or terms, such as “about”, is not limited to the precise value specified. In some instances, the approximating language may correspond to the precision of an instrument for measuring the value.

In the following specification and the claims, the singular forms “a”, “an” and “the” include plural referents unless the context clearly dictates otherwise. As used herein, the term “or” is not meant to be exclusive and refers to at least one of the referenced components (for example, a layer) being present and includes instances in which a combination of the referenced components may be present, unless the context clearly dictates otherwise.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable, or suitable. For example, in some circumstances, an event or capacity can be expected, while in other circumstances the event or capacity cannot occur—this distinction is captured by the terms “may” and “may be”.

The terms “transparent region”, “transparent layer” and “transparent electrode” as used herein, refer to a region, a layer, or an article that allows an average transmission of at least 80% of incident electromagnetic radiation having a wavelength in a range from about 300 nanometers to about 850 nanometers. As used herein, the term “disposed on” refers to layers disposed directly in contact with each other or indirectly by having intervening layers therebetween.

In the present disclosure, when a layer is being described as “on” another layer or substrate, it is to be understood that the layers can either be directly contacting each other or have another layer or feature between the layers. Thus, these terms are simply describing the relative position of the layers to each other and do not necessarily mean “on top of” since the relative position above or below depends upon the orientation of the device to the viewer. Moreover, the use of “top,” “bottom,” “above,” “below,” and variations of these terms is made for convenience, and does not require any particular orientation of the components unless otherwise stated.

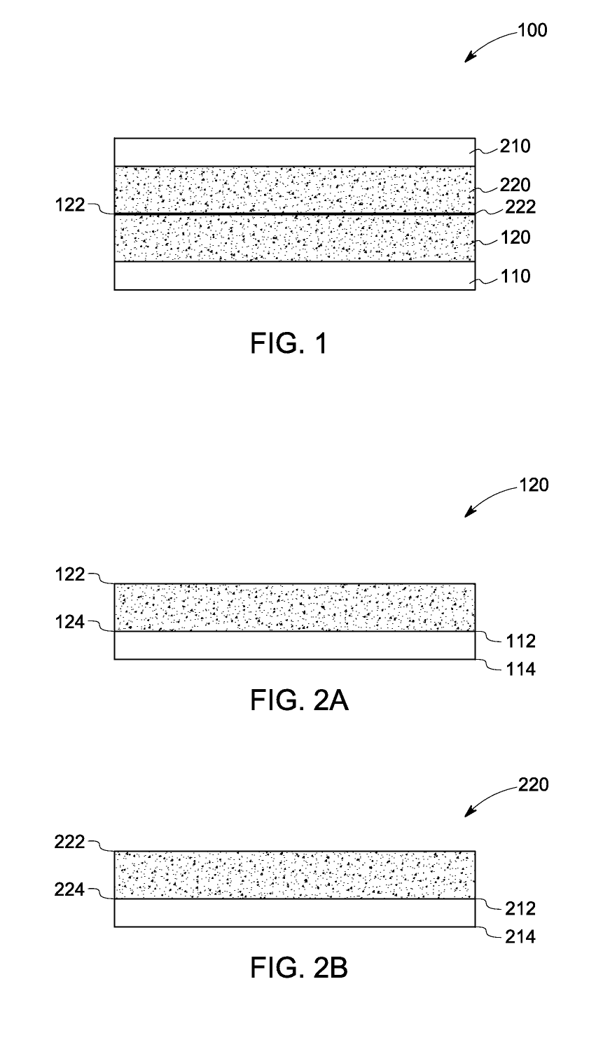

As discussed in detail below, some embodiments of the invention are directed to a method for forming a transparent layer. The method is described with reference to FIGS. 1-14. In one embodiment, as indicated, for example in FIGS. 1, 5, 7, 9, 11 and 13, the method includes thermally processing an assembly 100 including a first panel 101 and a second panel 201. In some embodiments, the assembly 100 may be a pre-fabricated assembly 100 or the method may include fabricating the assembly 100 by procuring one or more sub-components thereof and assembling the sub-components to form the assembly 100.

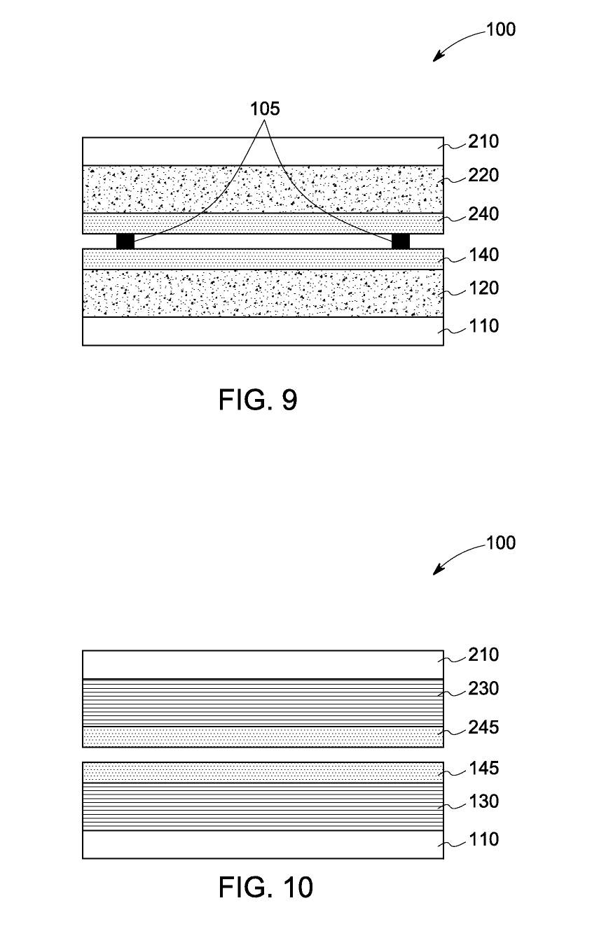

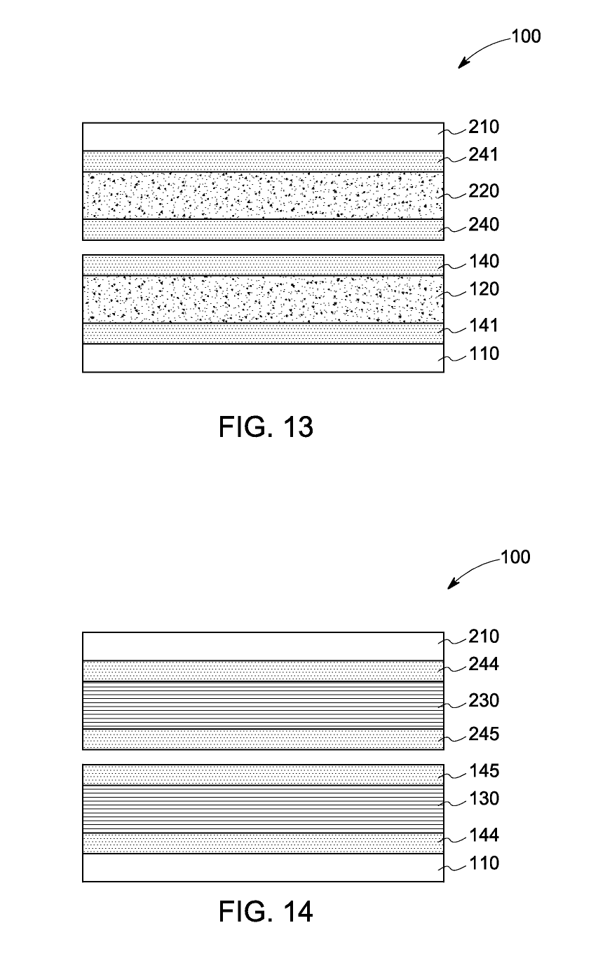

As further indicated in FIGS. 1, 5, 7, 9, 11 and 13, in some embodiments, the first panel 101 includes a first layer 120 disposed on a first support 110 and the second panel 201 includes a second layer 220 disposed on a support 210. Furthermore, as indicated, for example in FIGS. 9 and 13, in some embodiments, the first panel 101 includes a first getter layer 140 disposed on the first layer 120 and the second panel 201 includes a second getter layer 240 disposed on the second layer 220.

Further, as indicated, for example in FIGS. 1, 5, 7, 9, 11 and 13, the first panel 101 and the second panel 201 are assembled to form an assembly 100 such that the second panel faces the first panel or vice versa. The term “faces” as used herein means that the panels are configured in such a way that the first layer 120 and the second layer 220 face each other, or in embodiments including the getter layer the first getter layer 140 and the second getter layer 240 face each other. Further, as used herein, the term “faces” refers to layers or panels disposed directly in contact with each other or alternatively separated from other each other using a spacer disposed therebetween.

In some embodiments, the method includes assembling the first panel 101 and the second panel 201 to form the assembly 100. In some embodiments, the first panel 101 or the second panel 201 may be pre-fabricated or the method may include fabricating the first panel 101 or the second panel 201 by disposing one or more layers on the support (as discussed later) to form the panel(s).

As noted earlier, the method includes annealing cadmium tin oxide layers to form at least one transparent layer. In some embodiments, the first layer 120 and the second layer 220 include substantially amorphous cadmium tin oxide (CTO). In some embodiments, the method further includes disposing a substantially amorphous CTO layer on the first support 110 to form the first layer 120. In some embodiments, the method further includes disposing a substantially amorphous CTO layer on the second support 210 to form the second layer 220.

As used herein, the term “cadmium tin oxide” includes a composition of cadmium, tin, and oxygen. In some embodiments, cadmium tin oxide includes a stoichiometric composition of cadmium and tin, wherein, for example, the atomic ratio of cadmium to tin is about 2:1. In some other embodiments, cadmium tin oxide includes a non-stoichiometric composition of cadmium and tin, wherein, for example, the atomic ratio of cadmium to tin is in range less than about 2:1 or greater than about 2:1. As used herein, the terms “cadmium tin oxide” and “CTO” may be used interchangeably. In some embodiments, cadmium tin oxide may further include one or more dopants, such as, for example, copper, zinc, calcium, yttrium, zirconium, hafnium, vanadium, tin, ruthenium, magnesium, indium, zinc, palladium, rhodium, titanium, or combinations thereof. “Substantially amorphous cadmium tin oxide” as used herein refers to a cadmium tin oxide layer that does not have a distinct crystalline pattern as observed by X-ray diffraction (XRD).

In certain embodiments, CTO may function as a transparent conductive oxide (TCO). The electrical properties of CTO may depend in part on the composition of CTO characterized in some embodiments by the atomic concentration of cadmium and tin, or alternatively in some other embodiments by the atomic ratio of cadmium to tin in CTO. Atomic ratio of cadmium to tin, as used herein, refers to the ratio of atomic concentration of cadmium to tin in CTO. Atomic concentrations of cadmium and tin and the corresponding atomic ratio are commonly measured using, for instance, x-ray photoelectron spectroscopy (XPS).

In one embodiment, the atomic ratio of cadmium to tin in the first layer 120 or the second layer 220 is in a range from about 1:1 to about 3:1. In one embodiment, the atomic ratio of cadmium to tin in the first layer 120 or the second layer 220 is in a range from about 1.5:1 to about 2.5:1. In one particular embodiment, the atomic ratio of cadmium to tin in the first layer 120 or the second layer 220 is in a range from about 1.2:1 to about 2:1.

In one embodiment, the first layer 120 or the second layer 220 are disposed on the first support 110 or the second support 210 respectively by any suitable technique, such as sputtering, chemical vapor deposition, spin coating, spray pyrolysis, or dip coating. In a particular embodiment, the first layer 120 or the second layer 220 are disposed on the first support 110 or the second support 120 respectively by sputtering. The term “sputtering” as used herein refers to a physical vapor deposition (PVD) method of depositing thin films by ejecting material from a target or a source, which then deposits onto a substrate, such as, for example, support 110 or 210.

In one embodiment, the first layer 120 or the second layer 220 may be disposed on the first support 110 or the second support 210 respectively by magnetron sputtering. The term “magnetron sputtering” as used herein refers to sputter deposition or etching with the aid of a magnetron using crossed electric and magnetic fields. In one embodiment, the first layer 120 or the second layer 220 may be disposed on the first support 110 or the second support 210 respectively by radio frequency (RF) magnetron sputtering or by direct current (DC) magnetron sputtering. RF sputtering or DC sputtering refers to a sputtering method in which a RF power source or a DC power source is employed respectively during the sputtering process.

In one embodiment, the first layer 120 or the second layer 220 are disposed on the first support 110 or the second support 210 respectively by sputtering from one or more target comprising cadmium oxide, tin oxide, or combinations thereof. In some embodiments, the first layer 120 or the second layer 220 is disposed on the first support 110 or the second support 210 respectively by co-sputtering, wherein a first target includes cadmium oxide and a second target includes tin oxide. In some embodiments, the first layer 120 or the second layer 220 is disposed on the first support 110 or the second support 210 respectively by sputtering from a single target including a combination of cadmium oxide and tin oxide. In one embodiment, the first layer 120 or the second layer 220 is disposed on the first support 110 or the second support 210 respectively using a ceramic cadmium tin oxide target.

In one embodiment, the first layer 120 or the second layer 220 is disposed on the first support 110 or the second support 210 by reactive sputtering. The term “reactive sputtering” as used herein refers to a sputtering method wherein the deposited film is formed by chemical reaction between the material ejected from the target and a reactive gas which is introduced into the vacuum chamber. The composition of the film may be controlled by varying the relative pressures of the inert and reactive gases. In one embodiment, the first layer 120 or the second layer 220 is disposed on the first support 110 or the second support 210 by reactive sputtering in the presence of a reactive gas such as oxygen. In one embodiment, the first layer 120 or the second layer 220 is disposed on the first support 110 or the second support 210 by reactive sputtering using a single metallic target, wherein the metallic target includes a mixture of cadmium and tin metals or by reactive co-sputtering using two different metal targets, such as, a cadmium target and a tin target.

The thickness, composition, and morphology of the sputtered first layer 120 or second layer 220 may depend in part on the sputtering conditions employed such as, for example, the target composition, type of sputtering gas employed, volume of sputtering gas, sputtering pressure, or the sputtering power. may be advantageously prepared according to some embodiments of the invention.

In one embodiment, the atomic ratio of cadmium to tin in the one or more sputtering target is in a range from about 1.2:1 to about 2.5:1. In another embodiment, the atomic ratio of cadmium to tin in the one or more sputtering target is in a range from about 1.4:1 to about 2.25:1. In yet another embodiment, the atomic ratio of cadmium to tin in the one or more sputtering target is in a range from about 1.5:1 to about 2:1. In one particular embodiment, the atomic ratio of cadmium to tin in one or more sputtering target is in a range from about 1.5:1 to about 1.8:1.

In one embodiment, the first layer 120 or the second layer 220 is disposed on the first support 110 or the second support 210 by sputtering using oxygen gas in the sputtering atmosphere. In another embodiment, the first layer 120 or the second layer 220 is disposed on the first support 110 or the second support 210 by sputtering using a mixture of oxygen and argon gases in the sputtering atmosphere. In some embodiments, the percentage content of oxygen gas is greater than about 30 percent by volume of the total amount of gas employed during the sputtering process. In some embodiments, the percentage content of oxygen gas is about 100 percent by volume of the total amount of gas employed during the sputtering process. In some other embodiments, the percentage content of oxygen gas is in a range from about 30 percent to about 100 percent by volume of the total amount of gas employed during the sputtering process.

In some embodiments, the thickness of the first layer 120 or the second layer 220 is controlled by varying one or more of the processing parameters employed during the disposing step. In one embodiment, the first layer 120 or the second layer 220 has a thickness in a range from about 100 nanometers to about 600 nanometers. In a particular embodiment, the first layer 120 or the second layer 220 has a thickness in a range from about 200 nanometers to about 400 nanometers.

FIG. 2 shows a disassembled assembly 100 including a first panel 101 and a second panel 201. As indicated, for example, in FIG. 2A, the first support 110 further includes a first surface 112 and a second surface 114, wherein in one embodiment, a second surface 124 of the first layer 120 is disposed adjacent to the first surface 112 of the first support 110. Similarly, as indicated, for example in FIG. 2B, a second surface 224 of the second layer 220 is disposed adjacent to the first surface 212 of the second support 210, in one embodiment. In some embodiments certain other layers may be disposed between the first layer 120 and the first support 110 or the second layer 220 and the second support 210, such as, for example, a reflective layer or a barrier layer (not shown).

In one embodiment, the first support 110 or the second support 210 are transparent over the range of wavelengths for which transmission through the first support 110 or the second support 210 is desired. In one embodiment, the first support 110 or the second support 210 may be transparent to visible light having a wavelength in a range from about 30 nanometers to about 1000 nanometers. In one embodiment, the thermal expansion coefficient of the first support 110 or the second support 210 is close to the thermal expansion coefficient of the first layer 120 or the second layer 220 to prevent cracking or buckling of the CTO during heat treatment. In some embodiments, the first support 110 or the second support 210 includes a material capable of withstanding heat treatment temperatures greater than about 600° C., such as, for example silica and borosilicate glass. In some other embodiments, the first support 110 or the second support 210 includes a material that has a softening temperature lower than 600° C., such as, for example, soda-lime glass. In some embodiments, the first support 110 or the second support 210 may further include a reflective coating.

As noted earlier, in some embodiments, after the steps of disposing the first layer 120 on the first support 110 to form the first panel 101 and disposing the second layer 220 on the second support 210 to form the second panel, the panels 101 and 201 may be assembled to face each other.

In one embodiment, as indicated, for example, in FIG. 1, the first panel 101 and the second panel 201 may be assembled to face each other such that the first layer 120 is disposed adjacent to the second layer 220. The term “adjacent” as used herein means that the layers are contiguous to each other or in direct physical contact with each other. As indicated, for example, in FIG. 1, in such embodiments, a first surface 112 of the first layer 120 is disposed adjacent to the first surface 222 of the second layer 220.

In such embodiments, the method may further include purging the first surface 112 of the first layer 120 and a first surface 220 of the second layer 220 independently before assembling the two panels to form the assembly. In some embodiments, the step of purging may include flowing a high purity inert gas across the first surfaces 112 and 222 of the first layer 120 and second layer 220, respectively. Without being bound by any theory, it is believed that purging of the first layer 120 and the second layer 220 may lead to removal of any residual oxygen or moisture absorbed on CTO's surface.

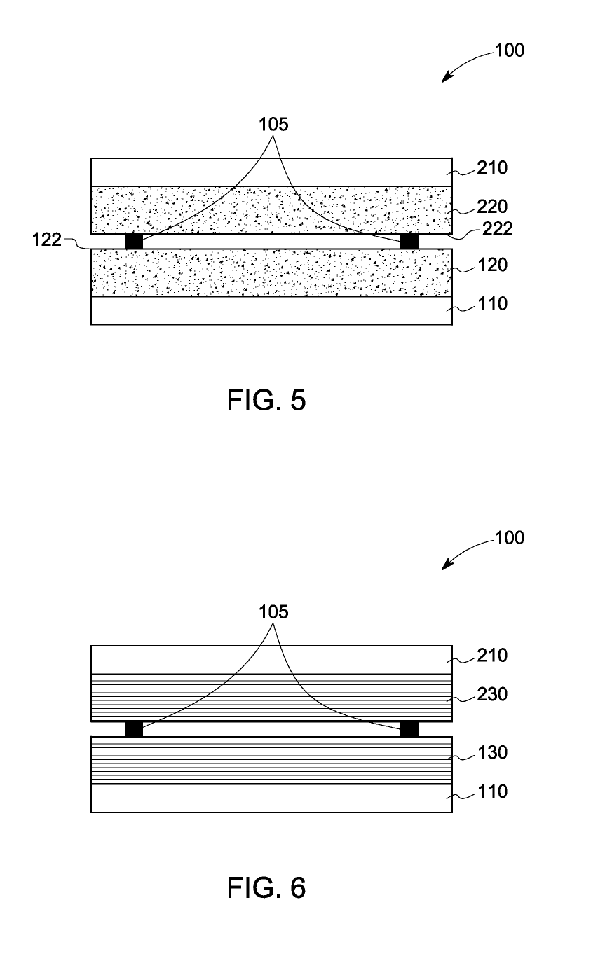

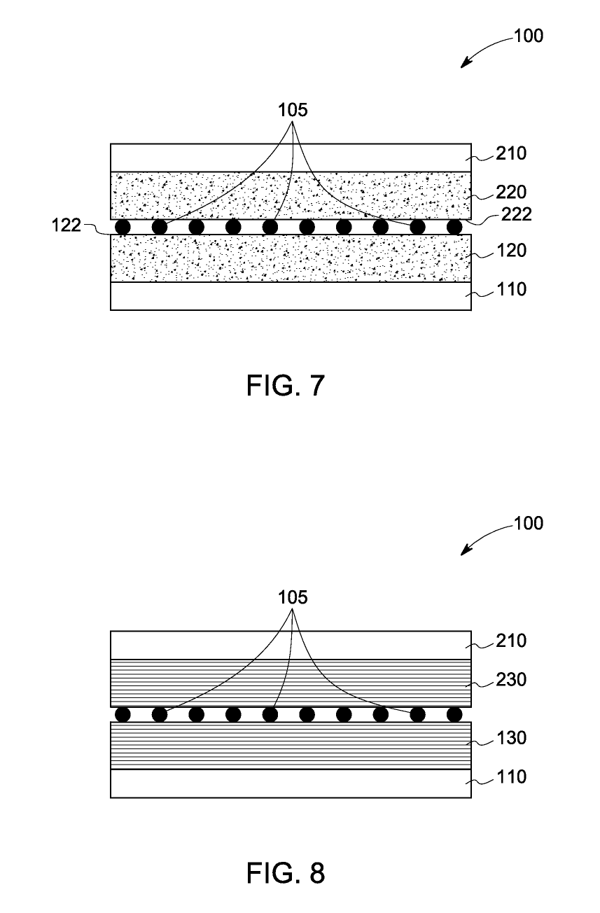

In one embodiment, as indicated, for example, in FIGS. 5 and 7, the first panel 101 and the second panel 201 may be assembled to face each other such that the first layer 120 is spaced apart from the second layer 220. In one embodiment, as indicated, for example, in FIGS. 5 and 7, the assembly 100 further includes a spacer 105 disposed between the first panel 101 and the second panel 201 to maintain a gap between the first panel 101 and the second panel 201. In some embodiments, any suitable spacer having the required structural characteristics capable of withstanding the thermal processing conditions (as described later) may be used for separating the first panel 101 and the second panel 201 and for maintaining the gap.

In one embodiment, as indicated, for example, in FIG. 5, the spacer 105 includes a plurality of wires configured to separate the first panel 101 from the second panel 201. In one embodiment, the first layer 120 and the second layer 220 are spaced apart from each other at a distance in a range from about 0.10 millimeters to about 6 millimeters. Without being bound by any theory, it is believed that by maintaining a gap between the two panels, the residual oxygen or moisture, which may be trapped between the two panels, may be removed resulting in lower resistivity of the transparent layers, in some embodiments.

In one embodiment, as indicated, for example, in FIG. 7, the spacer 105 includes a particulate material disposed on at least a portion of a surface of the first layer 120, the second layer 220, or both.

In some embodiments, the method further includes disposing the particulate material on at least a portion a first surface 122 of the first layer 120, the first surface 222 of the second layer 220, or both before assembling the panels 101 and 102 to form the assembly 100. In some embodiments, the particulate material may be disposed by mechanical spreading, vibrational mechanical spreading, electrostatic spraying, vapor transport deposition, or combinations thereof. In some embodiments, the particulate material may be disposed only on a portion of the first layer 120, the second layer 220, or both. In some embodiments, the particulate material is disposed such that the particulate material allows for separation of the two panels.

In some embodiments, the particulate material may have a variety of shapes and cross-sectional geometries. In one embodiment, a particulate material may have a shape, such as, a sphere, a rod, a tube, a flake, a fiber, a plate, a wire, a cube, a block, or a whisker. In one embodiment, a cross-sectional geometry of the particulate material may be one or more of circular, ellipsoidal, triangular, rectangular, and polygonal. In one embodiment, the particulate material may include spherical particles. In one embodiment, a particulate material may include non-spherical particles. In one embodiment, the particulate material may be irregular in shape.

In some embodiments, the particulate material may have a suitable thickness and shape depending in part on one or more of the particulate material chemistry, the deposition conditions, and the gap desired between the two panels. In some embodiments, the particulate material has an average thickness in a range from about 0.10 millimeters to about 6 millimeters. The term “thickness” as used herein refers to refers to a dimension of the spacer between the first layer 120 and the second layer 220, and may refer to a diameter of the spacer or height of the spacer.

In some embodiments, the particulate material includes cadmium. In some embodiments, the particulate material includes a cadmium compound. In some embodiments, the particulate material further includes a reducing agent. The term “reducing agent’ as used herein refers to a material capable of bringing about reduction, by depletion of oxygen or addition of hydrogen, in other materials by being itself oxidized in a chemical reaction. In some embodiments, the reducing agent includes sulfur. In some embodiments, the particulate material includes cadmium sulfide. In particular embodiments, the particulate material includes cadmium sulfide powder.

In some embodiments, the particulate material forms a substantially discontinuous layer of cadmium sulfide on the first surface 112 of the first layer, the first surface 222 of the second layer, or both. This is in contrast to method of using CdS film on a substrate for typical annealing of CTO, wherein the CdS forms a substantially continuous layer. Thus, the method of the present invention advantageously precludes the need for a separate film of CdS deposited on a substrate.

Without being bound by any theory, it is believed that cadmium sulfide as a particulate material may function as an oxygen getter material, in some embodiments. As used herein the term “oxygen getter material” refers to a material having a greater affinity for oxygen than the CTO (for example, be more reactive with oxygen). In some embodiments, the oxygen getter material is capable of removing a portion of oxygen from the first layer 120 or the second layer 220 during thermal processing. In some embodiments, oxygen from the first layer 120 or the second layer 220 may migrate to the particulate material during thermal processing, such that the transparent layers 130 and 230 have lower oxygen concentration than the as-deposited first layer 120 or the second layer 220. Without being bound by any particular theory, it is believed that the movement of oxygen from the first layer 120 or the second layer 220 during thermal processing may promote oxygen vacancies in the first transparent layer 130 or the second transparent layer 230, which may lead to higher carrier concentration and higher conductivity.

Further, without being bound by any theory, it is believed that in some embodiments, the particulate material may advantageously provide for containment of cadmium in the first layer 120 or the second layer 220 by limiting the diffusion of cadmium from the first layer 120 or the second layer 220 during the thermal processing, thereby increasing carrier concentration and optical transmission. Furthermore, in some embodiments, the particulate material may advantageously for a rough surface and thus preclude the first panel 101 and the second panel 201 from sticking to each other and provide for ease of separation of the two panels after thermal processing.

In one embodiment, as indicated, for example, in FIGS. 9, 11 and 13, at least one of the first panel 101 or the second panel 201 further includes one or more getter layer. The term “getter layer” as used in this context refers to a layer including an oxygen getter material. As used in this context the term “oxygen getter material” refers to a material having a greater affinity for oxygen than the CTO (for example, more reactive with oxygen). In some embodiments, the oxygen getter material is capable of removing a portion of oxygen from the first layer 120 or the second layer 220 during thermal processing. In some embodiments, oxygen from the first layer 120 or the second layer 220 may migrate to the getter layer during thermal processing, such that the transparent layers 130 and 230 have lower oxygen concentration than the as-deposited first layer 120 or the second layer 220. Without being bound by any particular theory, it is believed that the movement of oxygen from the first layer 120 or the second layer 220 during thermal processing may promote oxygen vacancies in the first transparent layer 130 or the second transparent layer 230, which may lead to higher carrier concentration and higher conductivity.

In some embodiments, the one or more getter layer includes a material having a greater affinity for oxygen that CTO. In some embodiments, the one or more getter layer may be substantially free from oxygen when deposited, such as, prior to thermal processing. As used herein, the term “substantially free” means the amount of oxygen in the as-deposited getter layer is less than about 0.01 molar percent. In some embodiments, the amount of oxygen in the as-deposited getter layer is less than about 0.01 molar percent. Further, the term “substantially free” encompasses completely free. In some other embodiments, the one or more getter layer includes a partially oxidized material.

In some embodiments, the getter layer includes a metal, a metal oxide, or combinations thereof. In some embodiments, the getter layer includes tin, zinc, aluminum, tantalum, titanium, zirconium, vanadium, indium, nickel, magnesium, or combinations thereof. In some embodiments, the getter layer includes elemental metal selected from the above-mentioned metals. In some other embodiments, the getter layer includes a partial metal oxide of one or more of the above-mentioned metals. In one embodiment, the one or more getter layer has a thickness in a range from about 5 nanometers to about 40 nanometers. In one embodiment, the one or more getter layer has a thickness in a range from about 10 nanometers to about 25 nanometers.

As noted earlier, one or both the first panel 101 and the second panel 201 include the one or more getter layer. In some embodiments, the first panel 101 includes the getter layer and the getter layer is disposed on the first layer 120, between the first layer 120 and the first support 110, or both on the first layer 120 and between the first layer 120 and the first support 110. In some embodiments, the second panel 201 includes the getter layer and the getter layer is disposed on the second layer 220, between the second layer 220 and the second support 210, or both on the second layer 220 and between the second layer 220 and the second support 110.

In some embodiments, as indicated, for example in FIG. 9, both the first panel 101 and the second panel 202 include the getter layers 140 and 240. In alternate embodiments, only one of the first panel 101 or the second panel 201 includes the getter layer (not shown). In one embodiment, as indicated, for example in FIG. 9, the first panel 101 includes a first getter layer 140 disposed on the first surface 122 of the first layer 120 (first top getter layer). Similarly, as indicated, for example in FIG. 9, the second panel 201 includes a second getter layer 240 disposed on the first surface 222 of the second layer 220 (second top getter layer).

Further, as indicated, for example in FIG. 9, the first panel 101 and the second panel 201 are configured in such embodiments such that the first getter layer 140 faces the second getter layer 240. As noted earlier, in some embodiments, the first panel 101 and the second panel 201 may be assembled such that there is a gap between the first getter layer 140 and the second getter layer 240, as indicated, for example in FIG. 9. In alternate embodiments, the first panel 101 and the second panel 201 may be assembled such that the first getter layer 140 and the second getter layer 240 are disposed adjacent to each other, such as, directly in physical contact with each other (not shown). In embodiments wherein a gap is maintained between the first panel 101 and the second panel 201, a spacer 105 may be used to maintain the gap.

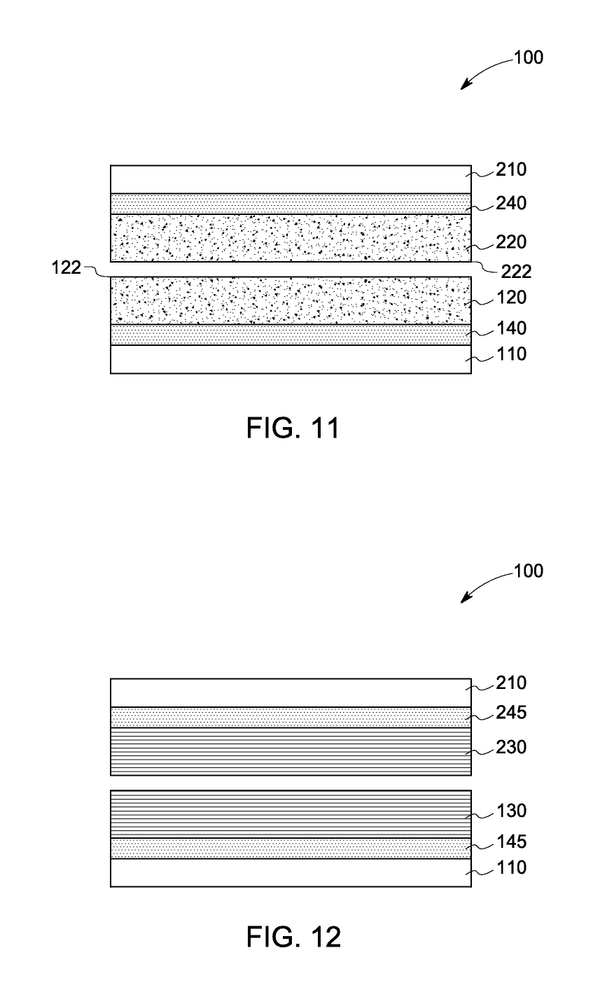

In one embodiment, as indicated, for example in FIG. 11, the first panel 101 includes a first getter layer 140 interposed between the first layer 120 and the first support 110 (first bottom getter layer). Similarly, as indicated, for example in FIG. 11, the second panel 201 includes a second getter layer 240 interposed between the second layer 220 and the first support 210 (second bottom getter layer). Further, as indicated in FIG. 11, the first panel 101 and the second panel 201 are configured in such embodiments such that the first layer 120 faces the second layer 220. As noted earlier, in some embodiments, the first panel 101 and the second panel 201 may be assembled such that there is a gap between the first layer 120 and the second layer 220. In alternate embodiments, the first panel 101 and the second panel 201 may be assembled such that the first layer 120 and the second layer 220 are disposed adjacent to each other, such as, directly in physical contact with each other (not shown). In embodiments wherein a gap is maintained between the first panel 101 and the second panel 201, a spacer 105 may be used to maintain the gap.

In one embodiment, as indicated, for example, in FIG. 13, the first panel 101 includes both a first top getter layer 140 disposed on the first surface 112 of the first layer 120 and a first bottom getter layer 141 interposed between the first layer 120 and the first support 110. Similarly, as indicated, for example in FIG. 13, the second panel 201 includes a second top getter layer 240 disposed on the first surface 222 of the second layer 220 and a second bottom getter layer 241 interposed between the second layer 220 and the first support 210. Further, as indicated, for example in FIG. 13, the first panel 101 and the second panel 201 are configured in such embodiments such that that the first top getter layer 140 faces the second top getter layer 240. As noted earlier, the first panel 101 and the second panel 201 may be assembled such that there is a gap or alternatively the getter layers are disposed adjacent to each other.

In certain embodiments, the first top getter layer 140 and the first bottom getter layer 141 may be in direct contact with the first layer 120 to maximize oxygen movement during thermal processing. Similarly, in certain embodiments, the second top getter layer 240 and the second bottom getter layer 241 may be in direct contact with the second layer 220 to maximize oxygen movement during thermal processing. Further, in such embodiments, the first top getter layer 140 and the first bottom getter layer 141 or the second top getter layer 240 and the second bottom getter layer 241 may include the same getter material or different getter materials.

In one embodiment, the method may further include disposing one or more getter layer on the first layer 120, the second layer 220, the first support 110, or the second support 210. In some embodiments, the one or more getter layer is deposited by sputtering, chemical vapor deposition, spray pyrolysis, or any other suitable deposition method. In embodiments wherein the one or more getter layer(s) is deposited to be substantially free from oxygen, the getter layer(s) may be sputtered from a metal target in an atmosphere that is substantially free of oxygen, such as, an inert atmosphere (for example, argon).

In embodiments, wherein the bottom getter layer is interposed between the first layer 120 and the first support 110 or between the second layer 220 and the second support, the getter layer may be first deposited on the support followed by deposition of CTO on the getter layer using a suitable technique as described earlier. Further, in some embodiments, the top getter layer may be then deposited on the first layer 120 or the second layer 220.

As noted earlier, in some embodiments, the one or more getter layer(s) may advantageously provide for removal of a portion of oxygen from the CTO layer during thermal processing, thereby increasing carrier concentration. Further, without being bound by any theory, it is believed that in some embodiments, the one or more top getter layer(s) may advantageously provide for containment of cadmium in the first layer 120 or the second layer 220 by limiting the diffusion of cadmium from the first layer 120 or the second layer 220 during the thermal processing, thereby increasing carrier concentration and optical transmission. Furthermore, in some embodiments, the one or more top getter layer(s) may advantageously provide for a rough surface and thus preclude the first panel 101 and the second panel 201 from sticking to each other and provide for ease of separation of the two panels after thermal processing.

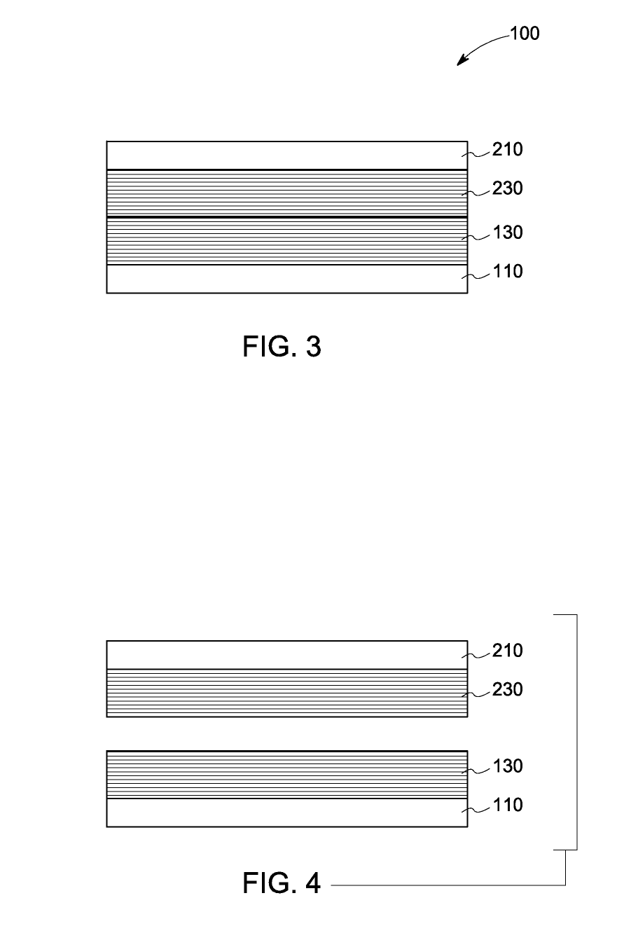

As noted earlier, the method further includes thermally processing the assembly 100 to form at least one transparent layer. The as-deposited CTO in the first layer 120 or the second layer 220 is substantially amorphous. In some embodiments, thermally processing the assembly 100 forms one or both of a first transparent layer 130 and a second transparent layer 230. The first transparent layer 130 and the second transparent layer 230 include cadmium tin oxide having a substantially single-phase spinel crystal structure, as indicated, for example in FIGS. 3, 6, 8, 10, 12, and 14. Accordingly, the thermal processing methods described herein eliminate the additional step of preparing a CdS film on a separate substrate that is typically used for annealing of CTO. Further, it also reduces the amount of CdS used in the fabrication of a photovoltaic device, and is economically advantageous as CdS is an expensive material.

In one embodiment, thermal processing of the assembly 100 includes heating the assembly 100 at a treatment temperature, under vacuum conditions, and for time duration sufficient to allow formation of one or both the first transparent layer 130 and the second transparent layer 230 having the desired electrical and optical properties. The composition, thickness, morphology, electrical properties, and optical properties of one or both the first transparent layer 130 and the second transparent layer 230 may be advantageously controlled by varying one or more of treatment temperature, time duration of heat treatment, and vacuum conditions employed during heat treatment.

In one embodiment, the first layer 120, the second layer 220, or both are heated at a treatment temperature in a range from about 500° C. to about 700° C. In one embodiment, the first layer 120, the second layer 220, or both are heated at a treatment temperature in a range from about 550° C. to about 680° C. In one embodiment, the first layer 120, the second layer 220, or both are heated at a treatment temperature in a range from about 600° C. to about 650° C.

In one embodiment, the first layer 120, the second layer 220, or both are heated at the treatment temperature for a time duration in a range from about 1 minute to about 70 minutes. In one embodiment, the first layer 120, the second layer 220, or both are heated at the treatment temperature for a time duration in a range from about 10 minutes to about 60 minutes. The time duration for annealing refers to the time for which the first layer 120, the second layer 220, or both are subjected to the annealing temperature in the annealing furnace. The time duration for annealing does not include the initial ramping period during which the first layer 120 or the second layer 220 is ramped to the annealing temperature.

The thermal annealing process is further controlled by varying the pressure conditions employed during thermal processing. In one embodiment, thermal annealing is carried out under vacuum conditions, defined here in as pressure conditions less than atmospheric pressure. In some embodiments, thermal processing may be carried out in the presence of argon or nitrogen gas at a constant pressure. In some other embodiments, thermal processing may be carried out under dynamic pressure by continuous pumping.

In some embodiments, thermal processing is conducted at a pressure less than about 10⁻³ Torr. In some embodiments, thermal processing is conducted at a pressure in a range from about 10⁻⁵ Torr to about 10 Torr. In some embodiments, thermal processing is conducted at a pressure less than about 500 Torr. In some embodiments, thermal processing is conducted at a pressure in a range from about 90 Torr to about 490 Torr. In some other embodiments, thermal processing is conducted at a pressure in a range from about 500 Torr to about 1 bar. “Pressure conditions” as used herein refer to the actual pressure of the sample during the annealing process.

As noted above, the thermal annealing of the assembly results in formation of at least one transparent layer. In some embodiments, as indicated, for example in FIGS. 3, 6, 8, 10, 12, and 14, thermally processing the assembly 100 includes forming a first transparent layer 130, a second transparent layer 230, or both. In particular embodiments, the method includes forming a first transparent layer 130 and the second transparent layer 230 after the thermal processing step. As noted earlier, in some embodiments, methods of the present invention advantageously provide for higher throughputs and reduced manufacturing costs by manufacturing two transparent layers using one thermal processing step.

In one embodiment, the first transparent layer 130 or the second transparent layer 230 includes substantially uniform single-phase polycrystalline CTO, formed for example, by annealing the substantially amorphous CTO. In some embodiments, the substantially crystalline CTO has an inverse spinel crystal structure. The substantially uniform single-phase crystalline CTO that forms the first transparent layer 130 or the second transparent layer 230 is referred to herein as “cadmium tin oxide” as distinguished from a “substantially amorphous CTO” thermally treated to form the transparent layer. In some embodiments, the first transparent layer 130 or the second transparent layer 230 may have the desired electrical and optical properties and may function as a transparent conductive oxide (TCO) layer. In some embodiments, first transparent layer 130 or the second transparent layer 230 may further include an amorphous component, such as for example, amorphous cadmium oxide, amorphous tin oxide, or combinations thereof.

The first transparent layer 130 or the second transparent layer 230 may be further characterized by one or more of thickness, electrical properties, and optical properties. In some embodiments, the first transparent layer 130 or the second transparent layer 230 has a thickness in a range from about 100 nanometers to about 600 nanometers. In some embodiments, first transparent layer 130 or the second transparent layer 230 has a thickness in a range from about 150 nanometers to about 450 nanometers. In certain embodiments, the first transparent layer 130 or the second transparent layer 230 has a thickness in a range from about 100 nanometers to about 400 nanometers. In some embodiments, the first transparent layer 130 or the second transparent layer 230 has an average optical absorption less than about 20%. In some embodiments, the first transparent layer 130 or the second transparent layer 230 has an average optical absorption less than about 10%. In certain embodiments, the first transparent layer 130 or the second transparent layer 230 has an average optical absorption less than about 5%.

The first transparent layer 130 or the second transparent layer 230, which may function as a TCO layer may be further characterized by its electrical resistivity. In some embodiments, the first transparent layer 130 or the second transparent layer 230 has an electrical resistivity (ρ) that is less than about 2×10⁻⁴ Ohm-cm. In some embodiments, the first transparent layer 130 or the second transparent layer 230 has an electrical resistivity (ρ) that is less than about 1.75×10⁻⁴ Ohm-cm. In a particular embodiment, the first transparent layer 130 or the second transparent layer 230 has an electrical resistivity (ρ) that is less than about 1.5×10⁻⁴ Ohm-cm.

In embodiments including the one or more getter layer, the thermal processing step may further include oxidizing the one or more getter layer. Further, in some embodiments, the oxygen content of the first layer 120 or the second layer 220 may decrease and the oxygen content of the one or more getter layer(s) may increase after the step of thermal processing.

In some embodiments, the oxygen content of the first layer 120 or the second layer 220 after the step of thermal processing may decrease by about 0.1 molar % to about 25 molar % depending on its composition. In some embodiments, the oxygen content of the first layer 120 or the second layer 220 after the step of thermal processing may decrease by about 1 molar % to about 20 molar % depending on its composition.

In some embodiments, the oxygen content of the one or more getter layer may increase after the step of thermal processing to render the one or more getter layer partially oxidized or substantially fully oxidized from the as-deposited state. Thus, by way of example, a getter layer including Sn may be oxidized to SnO₂, getter layer including Al may be oxidized to Al₂O₃, getter layer including Ti may be oxidized to TiO₂, getter layer including Zn may be oxidized to ZnO, after the step of thermal processing. In some embodiments, the getter layer after the step of thermal processing may further include partially oxidized metals, such as, for example, SnO or partially oxidized aluminum oxide

As noted herein earlier, the thermal processing step is carried out in the absence of a CdS film that is conventionally used for annealing cadmium tin oxide. Accordingly, the thermal processing step of the present invention eliminates the additional step of preparing a sacrificial CdS film on a non-reusable-substrate that is typically used for annealing of cadmium tin oxide to obtain a crystalline CTO layer having the desired electrical and optical properties. Furthermore, by face-to-face annealing of two CTO layers, the annealing process of the present invention may also result in reduced processing time leading to higher throughputs, which may lead to lower manufacturing costs.

Some embodiments described herein advantageously allow for thermal processing of a plurality of substantially amorphous CTO layers to form a plurality of transparent layers. In some embodiments, thermal processing of two or more substantially amorphous CTO layers forms two or more transparent layers. Thus, by way of example, as indicated, for example in FIG. 18, in one embodiment, the method includes thermally processing a stack of a plurality of assemblies 100 to form a plurality of transparent layers. In some embodiments, as indicated, for example in FIG. 18, each assembly 100 includes a first panel 101 including a first layer 120 disposed on a first support 110 and a second panel 201 including a second layer 220 disposed on a second support 210, wherein the second panel 201 faces the first panel 101, and wherein the first panel 101 and the second panel 201 include substantially amorphous cadmium tin oxide. As noted earlier, and as indicated by way of example, in FIG. 18, the plurality of assemblies 100 may be separated from each other using one or more spacers 105, in some embodiments.

In some embodiments, the method further includes separating the first panel 101 from the second panel 201 after the step of thermal processing, as indicated for example in FIG. 4. In some embodiments, the first panel 101 including the first transparent layer 130 or the second panel 201 including the second transparent layer 230 may be further used for manufacturing a photovoltaic device as described later.

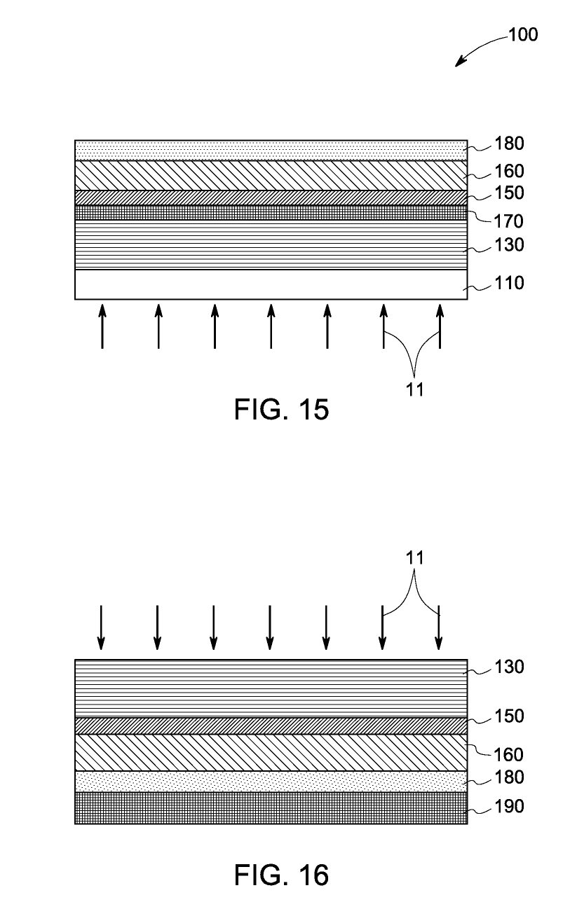

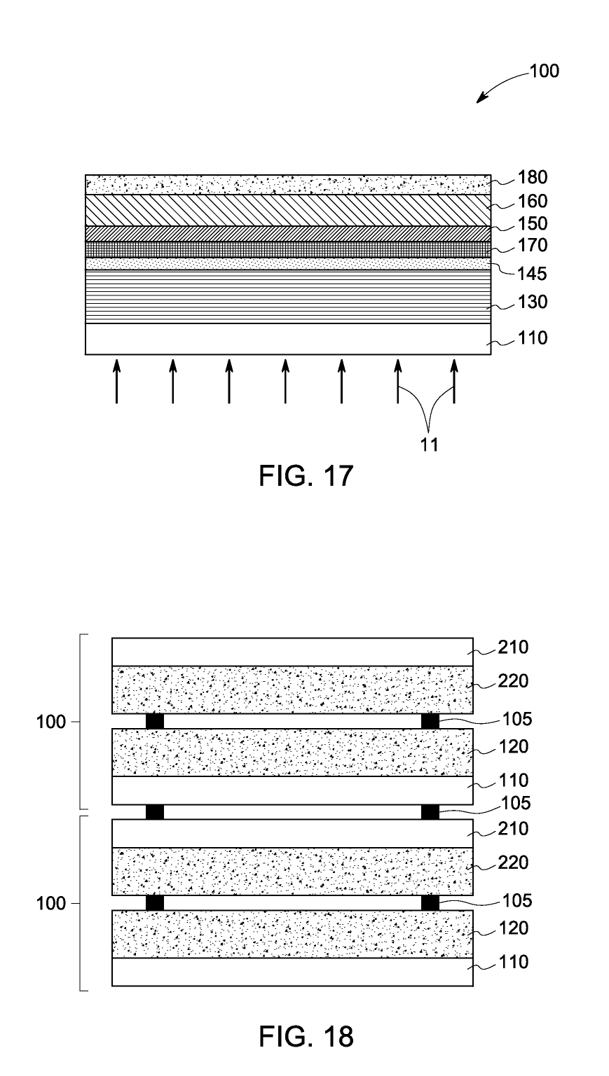

As discussed in detail below, some embodiments of the invention are further directed to methods for making photovoltaic devices. The method is described with reference to FIGS. 15-17, in some embodiments. As indicated, for example, in FIG. 15, after the step of thermally processing and separating the first panel 101 from the second panel 201, and using the first panel 101 by way of an example, the method further includes disposing a first semiconductor layer 150 on the transparent layer 130; disposing a second semiconductor layer 160 on the first semiconductor layer 140; and disposing a back contact layer 180 on the second semiconductor layer 160 to form a photovoltaic device 10. The configuration as shown in FIG. 15 is typically referred to as “superstrate” configuration, wherein, during service, the device is oriented so that the solar radiation 11 is incident on the support 110. Accordingly, in such a configuration, it is desirable that the support 110 is substantially transparent.

In one embodiment, the method includes making a photovoltaic device in a “substrate” configuration. The method includes forming a transparent layer 130 as described earlier on a support 110, such that the solar radiation 11 is incident on transparent layer 130, as shown in FIG. 16. In such embodiments, the support 110 includes a back contact layer 180 disposed on a back substrate 190, a second semiconducting layer 160 disposed on the back contact layer 180, a first semiconducting layer 150 disposed on the second semiconducting layer 160, and the transparent layer 130 disposed on the first semiconducting layer 150. In such a configuration as solar radiation is incident on the transparent layer 130, the back substrate 190 may include a metal.

In some embodiments, the first type semiconductor layer 150 and the second semiconductor layer 160 may be doped with a p-type dopant or n-type dopant to form a heterojunction. As used in this context, a heterojunction is a semiconductor junction, which is composed of layers of dissimilar semiconductor material. These materials usually have non-equal band gaps. As an example, a heterojunction can be formed by contact between a layer or region of one conductivity type with a layer or region of opposite conductivity, e.g., a “p-n” junction.

In some embodiments, the second semiconductor layer 160 includes an absorber layer. The absorber layer is a part of a photovoltaic device where the conversion of electromagnetic energy of incident light (for instance, sunlight) to electron-hole pairs (resulting in electrical current) occurs. A photo-active material is typically used for forming the absorber layer. Suitable photo-active materials include cadmium telluride (CdTe), cadmium zinc telluride (CdZnTe), cadmium magnesium telluride (CdMgTe), cadmium manganese telluride (CdMnTe), cadmium sulfur telluride (CdSTe), zinc telluride (ZnTe), copper indium sulphide (CIS), copper indium gallium selenide (CIGS), copper zinc tin sulphide (CZTS), or combinations thereof. The above-mentioned photo-active semiconductor materials may be used alone or in combination. Further, these materials may be present in more than one layer, each layer having different type of photo-active material or having combinations of the materials in separate layers. In one particular embodiment, the second semiconductor layer 160 includes cadmium telluride (CdTe) as the photo-active material. In one embodiment, the second semiconductor layer 160 has a thickness in a range from about 1500 nanometers to about 5000 nanometers.

In some embodiments, the second semiconductor layer 160 may be deposited by close-space sublimation (CSS), vapor transport method (VTM), ion-assisted physical vapor deposition (IAPVD), radio frequency or pulsed magnetron sputtering (RFS or PMS), plasma enhanced chemical vapor deposition (PECVD), or electrochemical deposition (ECD). In particular embodiments, the second semiconductor layer 160 may be deposited by close-space sublimation (CSS), diffused transport deposition (DTD), or vapor transport deposition (VTD).

The first semiconductor layer 150 is disposed adjacent to the transparent layer 130. In some embodiments, the first semiconductor layer 150 includes an n-type semiconductor material. In such embodiments, the second semiconductor layer 160 may be doped to be p-type, and the first semiconductor layer 150 and the second semiconductor layer 160 may form an “n-p” heterojunction. Non-limiting exemplary materials for the first semiconductor layer 150 include cadmium sulfide (CdS), oxygenated cadmium sulfide (CdS:O), indium III sulfide (In₂S₃), zinc sulfide (ZnS), zinc telluride (ZnTe), zinc selenide (ZnSe), cadmium selenide (CdSe), oxygenated cadmium sulfide (CdS:O), copper oxide (Cu₂O), zinc oxihydrate (ZnO,H), or combinations thereof. In a particular embodiment, the first semiconductor layer 150 includes cadmium sulfide (CdS) and may be referred to as the “window layer”. In one embodiment, the first semiconductor layer 150 has a thickness in a range from about 30 nanometers to about 150 nanometers. Non-limiting examples of the deposition methods for the first semiconductor layer 150 include one or more of close-space sublimation (CSS), vapor transport method (VTM), sputtering, and electrochemical bath deposition (CBD).

In some embodiments, the method further includes interposing a buffer layer 170 (sometimes referred to in the art as a higher resistance transparent (HRT) layer) between the first semiconductor layer 150 and the first transparent layer 130, as indicated, for example, in FIG. 15. In one embodiment, the thickness of the buffer layer 170 is in a range from about 50 nanometers to about 200 nanometers. Non-limiting examples of suitable materials for the buffer layer 170 include tin dioxide (SnO₂), zinc stannate (ZTO), zinc-doped tin oxide (SnO₂:Zn), zinc oxide (ZnO), indium oxide (In₂O₃), or combinations thereof.

A back contact layer 180 is further disposed adjacent to the second semiconductor layer 160 and is in ohmic contact therewith, in some embodiments. In some embodiments, the back contact layer 180 may include a metal, a semiconductor, or combinations thereof. In some embodiments, a back contact layer 180 may include graphite, gold, platinum, molybdenum, nickel, zinc telluride, or combinations thereof. In some embodiments, the back contact layer may include a single layer or a plurality of layers. In one embodiment, the back contact layer 180 may include graphite, deposited on the second semiconductor layer 160 followed by one or more layers of metal, such as the metals described above. Depending on the type of back contact layer, the one or more layers of the back contact layer 180 may be deposited using a suitable technique such as sputtering, metal evaporation, screen printing, spraying or by using a “doctor” blade.

In some embodiments, one or more additional layers may be interposed between the second semiconductor layer 160 and the back contact layer 180, such as, for example, a p+-type semiconductor layer. In some embodiments, the second semiconductor layer 160 may include p-type cadmium telluride (CdTe) that may be further treated or doped to improve the back contact resistance, such as for example, by cadmium chloride treatment or by forming a zinc telluride or copper telluride layer on the backside. In one embodiment, the back contact resistance may be improved by increasing the p− type carriers in the CdTe material to form a p+ type layer on the backside of the CdTe material that is in contact with the back contact layer 180.

One or more of the first semiconductor layer 150, the second semiconductor layer 160, the back contact layer 180, or the buffer layer 170 (optional) may be may be further heated or subsequently treated after deposition to manufacture the photovoltaic device 10.

In some embodiments, other components (not shown) may be included in the exemplary photovoltaic device 10, such as, buss bars, external wiring, laser etches, etc. For example, when the device 10 forms a photovoltaic cell of a photovoltaic module, a plurality of photovoltaic cells may be connected in series in order to achieve a desired voltage, such as through an electrical wiring connection. Each end of the series connected cells may be attached to a suitable conductor such as a wire or bus bar, to direct the generated current to convenient locations for connection to a device or other system using the generated current. In some embodiments, a laser may be used to scribe the deposited layers of the photovoltaic device 10 to divide the device into a plurality of series connected cells.

### EXAMPLES

The following examples are presented to further illustrate certain embodiments of the present invention. These examples should not be read to limit the invention in any way.

### Example 1

### Deposition of Cadmium Tin Oxide Layer from a Ceramic Target

Thin films of cadmium tin oxide (CTO) were prepared on a 1.3 mm thick glass support by non-reactive magnetron direct current (DC) sputtering from a pre-reacted cadmium stannate target having a Cd:Sn ratio of about 2:1. The sputtering process was performed in an atmosphere containing oxygen and argon (wherein the concentration of oxygen was greater than 90%) at a pressure of about 16 mTorr. The thickness of the sputtered CTO film was about 200 nanometers.

### Comparative Example 1

### Annealing of Cadmium Tin Oxide Layer Using CdS Film

Samples prepared in Example 1 were annealed by placing the CTO films prepared above in contact with a CdS-coated glass support (referred to herein as CdS proximity annealing or “CPA”). The assembly was heated to a temperature of 630° C. for about 20 minutes in the presence of nitrogen at a pressure of about 160 Torr to form Comparative Sample 1.

### Comparative Example 2

### Annealing of a Single Cadmium Tin Oxide Layer without CdS Film

Samples prepared in Example 1 were annealed by placing the CTO films prepared above in the absence of CdS-coated glass support. The CTO samples were annealed at 630° C. for 20 minutes in a three-zone tube furnace connected to a vacuum chamber, which was pre-heated to a temperature of 630° C. prior to annealing, under pressure conditions of 160 Torr to form Comparative Sample 2. Annealing in the absence of CdS or an external source of cadmium is referred to herein as standard thermal annealing process or “STA”.

### Example 2

### Face to Face Annealing of Cadmium Tin Oxide Layer without CdS Film

Samples prepared in Example 1 were annealed by placing two samples facing each other and separated using tungsten wires (diameter ˜0.25 millimeters) to maintain a gap of about 0.25 millimeters. The resulting assembly was placed in an annealing chamber and annealed at 630° C. for 20 minutes at a pressure of 160 Torr. After the annealing process, the assembly was cooled and the two CTO layers separated from each other to form Sample 1.

The sheet resistance of the samples prepared in Example 2 and Comparative Examples 1 and 2 was measured using a 4-point probe, locating the probe near the center of the sample. The total transmission and reflection were measured using a Cary UV-Vis spectrophotometer to compute the optical absorption as a function of wavelength. The total absorption was then computed between 325 and 850 nanometers weighted to the solar photon flux spectrum.

Table 1 shows the electrical properties for Sample 1 and Comparative Samples 1 and 2. As indicated in Table 1, face-to-face annealing of CTO layers results in comparable average resistivity values when compared to CTO layers annealed in the presence of CdS film (CPA) and lower resistivity values than the samples annealed in the absence of CdS film (STA). However, the CTO layers annealed by face-to-face annealing method have the highest optical transmission among the three annealing approaches.

TABLE 1
Electrical properties of Sample 1 and Comparative Samples 1 and 2

| | Average | | Average | |
|---|---|---|---|---|
| | Sheet | Average | Carrier | Average |
| | Resistance | Resistivity | Density | Mobility |
| Sample | (ohms/sq) | (ohms-cm) | (cm⁻³) | (cm² V⁻¹ s⁻¹) |
| Sample 1 | 4.52 | 1.36 × 10⁻⁴ | 6.99 × 10²⁰ | 65.9 |
| Comparative | 4.21 | 1.26 × 10⁻⁴ | 7.52 × 10²⁰ | 65.8 |
| Sample 1 | | | | |
| Comparative | 4.91 | 1.47 × 10⁻⁴ | 6.30 × 10²⁰ | 67.2 |
| Sample 2 | | | | |

### Example 3

### Effect of Gap Width on Face-to-Face Annealing of Cadmium Tin Oxide Layer

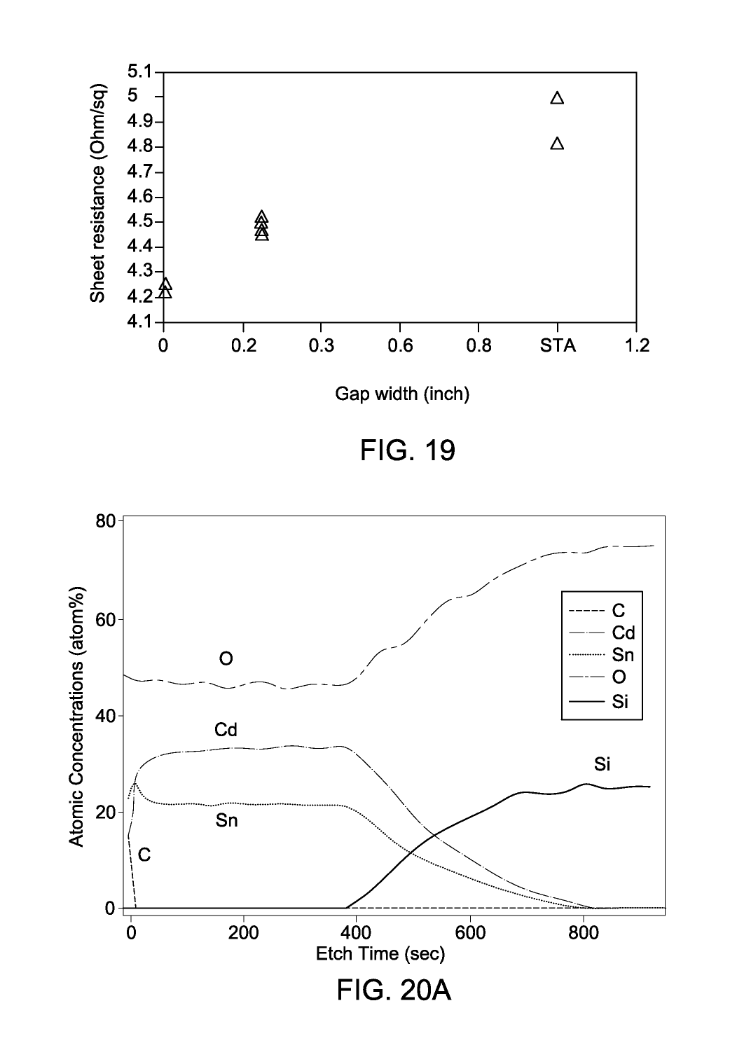

Samples prepared in Example 1 were annealed by placing two samples facing each other and separated using a spacer to maintain a gap width of about 0.127 millimeters (Sample 2) or 6 millimeters (Sample 3). To maintain a 0.127 millimeters gap, tungsten wires with a diameter of 0.127 millimeters were used and to maintain a gap of 6 millimeters, borosilicate glass block with thickness of 6 millimeters were used. Similarly, two samples were also assembled adjacent to each other such that there was no gap between the two CTO layers (Sample 4). The resulting assemblies were placed in an annealing chamber and annealed at 630° C. for 20 minutes at a pressure of 160 Torr. After the annealing process, the assemblies were cooled and the two CTO layers separated from each other. FIG. 19 shows the sheets resistance values measured for Samples 2 and 3 in comparison to Comparative sample 2. As illustrated in FIG. 19, samples annealed using face-to-face annealing show lower sheet resistance than samples annealed without face-to-face annealing.

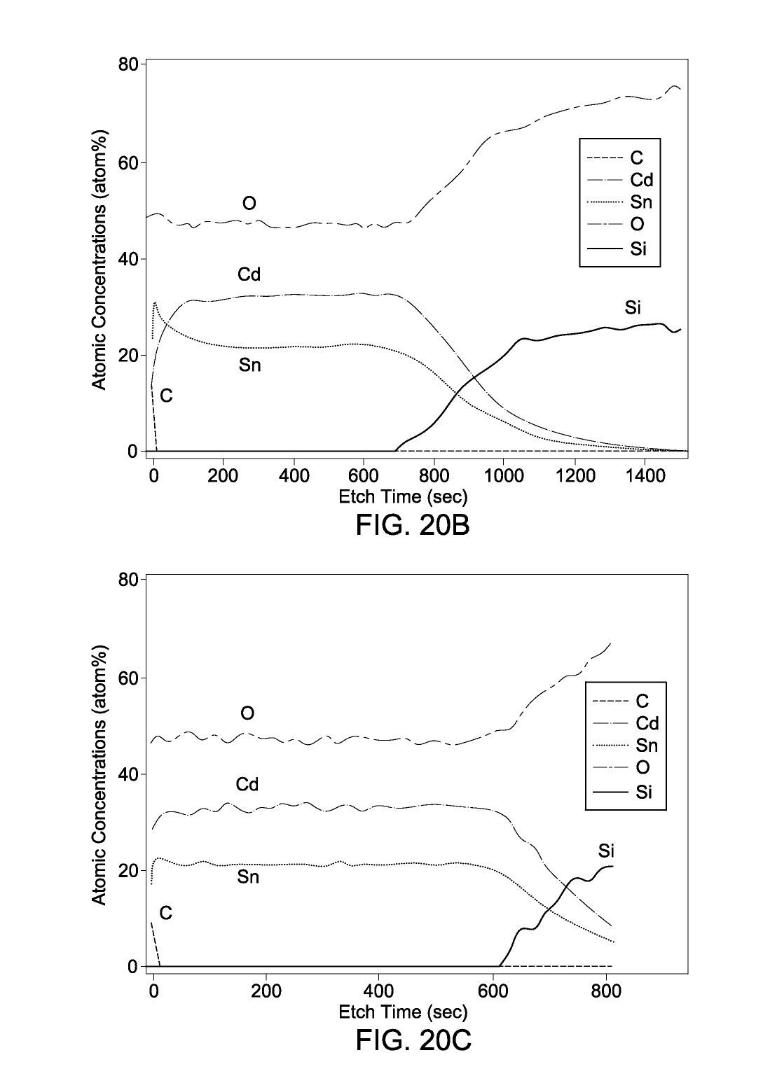

FIG. 20 shows the X-ray photoelectron spectroscopy (XPS) depth profile of the three CTO films: Sample 1, Comparative Sample 1 and Comparative Sample 2. FIG. 20 indicates that face-to-face annealing results in the lowest cadmium depletion near the CTO surface, although all three annealing approaches seem to result in almost identical bulk CTO composition.

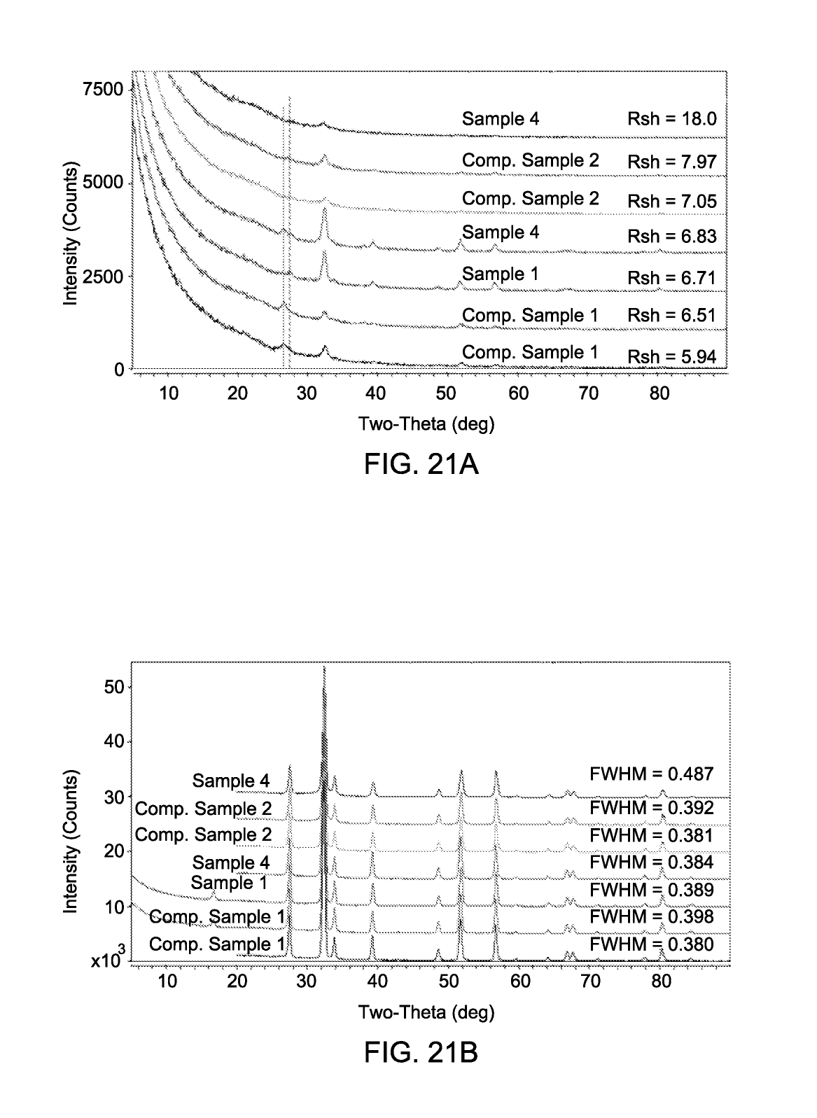

FIGS. 21A and 21B illustrate the structural properties of CTO films by using glancing incident X-ray diffraction (GIXRD). The GIXRD technique was used to examine the structure of the layers at different depths. At glancing incidence angles of 0.2 and 0.8 degrees, the X-ray penetration depth in the CTO film is about 5 nanometers and 89 nanometers, respectively. As can be seen from FIG. 21A, with glancing incidence angle of 0.2 degree, Comparative Sample 1 shows the existence of secondary phase (cassiterite SnO₂) together with the normal spinel CTO crystal structure. In comparison, no secondary phases were observed for Sample 1 and Comparative Sample 2. Further, the XRD peak for Sample 1 appears to be much stronger and sharper than that for Comparative Sample 1, which may indicate better crystalline surface of face-to-face annealed CTO layer because of lower Cd depletion from its surface. FIG. 21B shows the GIXRD pattern with the glancing incidence angle of 0.8 degree, and at this penetration depth, all three CTO samples shows the same spinel CTO crystal structure with almost identical crystallinity estimated from the peak full width at half maximum (FWHM) at two-theta of around 80 degree.

### Example 4

### Face-to-Face Annealing of Cadmium Tin Oxide Layer Using Getter Layers

Two separate 340 nanometers thick CTO films were deposited on two glass substrates using the method described in Example 1. The films were further coated with 12.5 nanometers thick tin films and assembled to form an assembly such that the tin layers face each other. The resulting assembly was annealed for 25 minutes at ˜625° C. in a nitrogen environment containing less than 2 ppm of O₂ to form Sample 5.

### Comparative Example 3

### Annealing of a Single Cadmium Tin Oxide Layer Using a Getter Layer

A single tin-coated CTO film prepared in Example 4 was annealed for 25 minutes at about 625° C. in a nitrogen environment containing less than 2 ppm of O₂ to form Example 4.

### Comparative Example 4

### Annealing of a Single Cadmium Tin Oxide Layer without a Getter Layer

A single CTO film prepared in Example 4, without the tin coating, was annealed for 25 minutes at about 625° C. in a nitrogen environment containing less than 2 ppm of O₂ to form Comparative Example 4.

After the anneal process, sheet resistance was measured using a hand-held 4-point probe. Table 2 shows the sheet resistance values for Sample 5 and Comparative Samples 3 and 4. As indicated in Table 2, face-to-face annealing of CTO layers with getter layers results in lower sheet resistance values when compared to CTO layers that are not annealed face-to-face.

TABLE 2
Sheet Resistance of Sample 5 and Comparative Samples 3 and 4

| | Sheet Resistance | Sheet Resistance |
|---|---|---|
| Sample | (ohms/sq) | (Standard Deviation) |
| Sample 5 | 3.5 | 0.26 |
| Comparative | 5.4 | 0.24 |
| Example 3 | | |
| Comparative | 8.2 | 0.42 |
| Example 4 | | |

### Example 5

### Face-to-Face Annealing of Cadmium Tin Oxide Layer Using Different Getter Layers

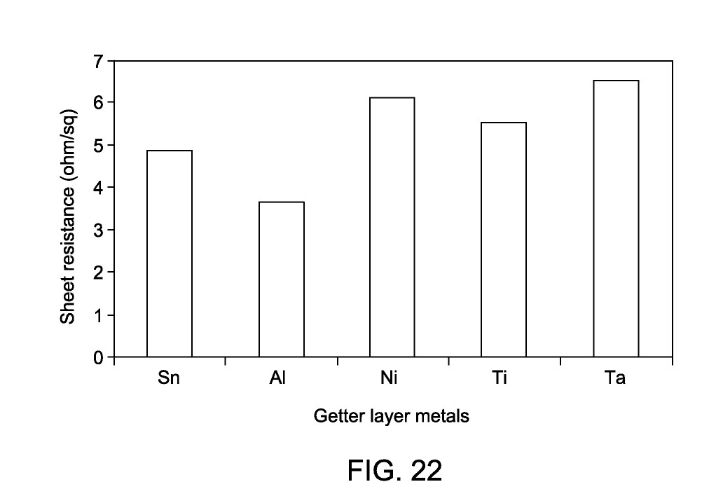

Two separate 340 nanometers thick CTO films were deposited on two glass substrate using the method described in Example 1. The films were further coated with 15 nanometers thick films of tin, aluminum, nickel, titanium, or tantalum getter layers. The CTO films were then assembled to form an assembly such that the getter layers face each other. The resulting assembly was annealed for 10 minutes at about 630° C. in a nitrogen environment containing less than 2 ppm of O₂. FIG. 22 shows the sheet resistance values for different getter layer materials.

The foregoing examples are merely illustrative, serving to exemplify only some of the features of the invention. The appended claims are intended to claim the invention as broadly as it has been conceived and the examples herein presented are illustrative of selected embodiments from a manifold of all possible embodiments. Accordingly, it is the Applicants' intention that the appended claims are not to be limited by the choice of examples utilized to illustrate features of the present invention. As used in the claims, the word “comprises” and its grammatical variants logically also subtend and include phrases of varying and differing extent such as for example, but not limited thereto, “consisting essentially of” and “consisting of.” Where necessary, ranges have been supplied; those ranges are inclusive of all sub-ranges there between. It is to be expected that variations in these ranges will suggest themselves to a practitioner having ordinary skill in the art and where not already dedicated to the public, those variations should where possible be construed to be covered by the appended claims. It is also anticipated that advances in science and technology will make equivalents and substitutions possible that are not now contemplated by reason of the imprecision of language and these variations should also be construed where possible to be covered by the appended claims.

1. A method, comprising:
thermally processing an assembly to form at least one transparent layer, wherein the assembly comprises:
a first panel comprising a first layer disposed on a first support and a second panel comprising a second layer disposed on a second support,
wherein the second panel faces the first panel, and wherein the first layer and the second layer comprise substantially amorphous cadmium tin oxide.

2. The method of claim 1, wherein the first layer and the second layer are disposed adjacent to each other.

3. The method of claim 1, wherein the first layer and the second layer are spaced apart from each other.

4. The method of claim 3, wherein the first layer and the second layer are spaced apart from each other at a distance in a range from about 0.10 millimeters to about 6 millimeters.

5. The method of claim 1, further comprising a spacer disposed between the first panel and the second panel to maintain a gap between the first panel and the second panel.

6. The method of claim 5, wherein the spacer comprises a particulate material disposed on at least a portion of a surface of the first layer, the second layer, or both.

7. The method of claim 6, wherein the particulate material comprises cadmium.

8. The method of claim 6, wherein the particulate material comprises a reducing agent.

9. The method of claim 6, wherein the particulate material comprises cadmium sulfide.

10. The method of claim 1, wherein at least one of the first panel or the second panel further comprises one or more getter layer.

11. The method of claim 10, wherein the first panel comprises the getter layer and the getter layer is disposed on the first layer, between the first layer and the first support, or both.

12. The method of claim 11, wherein the second panel comprises the getter layer and the getter layer is disposed on the second layer, between the second layer and the second support, or both.

13. The method of claim 10, wherein the getter layer comprises a metal, a metal oxide, or combinations thereof.

14. The method of claim 10, wherein the getter layer comprises tin, zinc, aluminum, tantalum, titanium, zirconium, vanadium, indium, nickel, magnesium, or combinations thereof.

15. The method of claim 1, wherein an atomic ratio of cadmium to tin in the first layer or the second layer is in a range from about 1:1 to about 3:1.

16. The method of claim 1, wherein thermal processing comprises heating the first layer, the second layer, or both at a treatment temperature in a range from about 500° C. to about 700° C.

17. The method of claim 1, wherein thermal processing comprises heating the first layer, the second layer, or both for a time duration in a range from about 1 minute to about 60 minutes.

18. The method of claim 1, wherein thermal processing is conducted at a pressure in a range from about 10⁻⁵ Torr to about 10 Torr.

19. The method of claim 1, wherein thermal processing is conducted at a pressure in a range from about 10 Torr to about 750 Torr.

20. The method of claim 1, wherein the transparent layer comprises cadmium tin oxide having a substantially single-phase spinel crystal structure.

21. The method of claim 1, wherein the transparent layer has a thickness in a range of from about 100 nanometers to about 500 nanometers.

22. The method of claim 1, wherein the transparent layer has an electrical resistivity less than about 2.0×10⁻⁴ Ohm-cm.

23. The method claim 1, wherein the transparent layer has an average optical absorption less than about 10%.

24. The method of claim 1, wherein thermally processing the assembly comprises forming a first transparent layer and a second transparent layer.

25. The method of claim 10, wherein thermal processing step further comprises oxidizing the one or more getter layer.

26. The method of claim 1, further comprising separating the first panel from the second panel.

27. A method, comprising:
thermally processing a stack comprising a plurality of assemblies to form a plurality of transparent layers, wherein each assembly comprises:
a first panel comprising a first layer disposed on a first support and a second panel comprising a second layer disposed on a second support,
wherein the second panel faces the first panel, and wherein the first layer and the second layer comprise substantially amorphous cadmium tin oxide.

28. A method of making a photovoltaic device, comprising:
thermally processing an assembly to form at least one transparent layer, wherein the assembly comprises:
a first panel comprising a first layer disposed on a first support and a second panel comprising a second layer disposed on a second support,
wherein the second panel faces the first panel, and wherein the first layer and the second layer comprise substantially amorphous cadmium tin oxide;
separating the first panel from the second panel;
disposing a first semiconductor layer on the transparent layer;
disposing a second semiconductor layer on the first semiconductor layer; and
disposing a back contact layer on the second semiconductor layer to form the photovoltaic device.

29. The method of claim 28, wherein the first semiconductor layer comprises cadmium sulfide.

30. The method of claim 28, wherein the second semiconductor layer comprises cadmium telluride.

31. The method of claim 28, further comprising disposing a buffer layer interposed between the transparent layer and the first semiconductor layer.

32. A method, comprising:
thermally processing an assembly to form a first transparent layer and a second transparent layer, wherein the assembly comprises:
a first panel comprising a first layer disposed on a first support and a first getter layer disposed on the first layer or between the first layer and the first support,
a second panel comprising a second layer disposed on a second support and a second getter layer disposed on the second layer or between the second layer and the second support,
wherein the first panel faces the second panel, and wherein the first layer and the second layer comprise substantially amorphous cadmium tin oxide.

33. The method of claim 32, wherein the first getter layer and the second getter layer comprise the same getter material.

34. The method of claim 32, wherein the first getter layer and the second getter layer comprise a getter material different from each other.

35. The method of claim 32, wherein the first getter layer and the second getter layer comprise a metal, a metal oxide, or combinations thereof.
